(19) United States
(12) Patent Application Publication
(10) Pub. No.: US 2013/0173973 A1
(43) Pub. Date: Jul. 4, 2013

(54) DEVICE

(71) Applicant: Elpida Memory, Inc., Tokyo (JP)

(72) Inventor: Ichiro ABE, Tokyo (JP)

(73) Assignee: Elpida Memory, Inc., Tokyo (JP)

(21) Appl. No.: 13/720,332

(22) Filed: Dec. 19, 2012

(30) Foreign Application Priority Data
Dec. 28, 2011 (JP) 2011-287359

(51) Int. Cl. G11C 29/08

(52) U.S. Cl. CPC G11C 29/08
USPC 714/718

(57) ABSTRACT

A device includes memory banks, each having a plurality of memory cells with respective error data output circuits. Each of the error data output circuits outputs first to M-th (M is an integer of 2 or more) error data according to first to M-th data retrieved from first to M-th memory cell groups selected from its corresponding memory bank. A test control circuit has first error data synthesis circuits and second to (M+1)-th error data synthesis circuits, each of which synthesizes the first to M-th error data from a corresponding error data output circuit and outputs the synthesized data as first test data. Each of the error data synthesis circuits synthesizes m-th (m is an integer of from 1 to M) error data from the error data output circuits and outputs the synthesized data as (m+1)-th test data.

This application claims priority to prior Japanese patent application JP 2011-287359, filed on Dec. 28, 2011, the disclosure of which is incorporated herein by reference.

### BACKGROUND OF THE INVENTION

This invention relates to a semiconductor device.

An example of a semiconductor device having a plurality of memory banks each having a plurality of memory cells is disclosed in Japanese Laid-Open Patent Publication No. 2003-338175 (Patent Document 1), for example.

### SUMMARY

Consideration is given to a case in which test operation is conducted, in a semiconductor device having a plurality of memory banks as the one described in Patent Document 1, in order to detect any defect in a plurality of memory cell groups in the memory banks.

In this test operation, when a plurality of test data corresponding to the plurality of memory cell groups of each memory bank are directly output outside the semiconductor device through data output terminals, the number of pieces of output test data corresponds to the number of selected memory cell groups. This causes a problem that a large number of pieces of data must be processed, requiring a long period of time for testing them. The inventor has conducted studies to develop a semiconductor device capable of shortening the time required for performing such test operation.

In one embodiment, there is provided a device that includes a plurality of memory banks each having a plurality of memory cells. A plurality of error data output circuits are provided in correspondence with the respective memory banks. Each of the error data output circuits outputs first to M-th (M is an integer of 2 or more) error data according to first to M-th data retrieved from first to M-th memory cell groups selected from its corresponding memory bank. A test control circuit has a plurality of first error data synthesis circuits each of which synthesizes the first to M-th error data from the corresponding one of the error data output circuits and outputs the synthesized data as first test data. The test control circuit further has second to (M+1)-th error data synthesis circuits each of which synthesizes m-th (m is an integer of from 1 to M) error data from the error data output circuits and outputs the synthesized data as (m+1)-th test data.

In another embodiment, there is provided a device that includes a plurality of memory banks each having first to M-th (M is an integer of 2 or more) sub memory banks. A plurality of error data output circuits are provided in correspondence with the respective memory banks, and includes first to M-th error detection circuits respectively corresponding to the first to M-th sub memory banks in the corresponding memory banks. A plurality of first synthesis circuits are respectively provided in correspondence with the plurality of error data output circuits to synthesize error data from the first to M-th error detection circuits of the corresponding error data output circuit. Each of second to (M+1)-th synthesis circuits synthesizes error data respectively from all the m-th (m is an integer of 1 to M) error detection circuits included in the plurality of error data output circuits.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing a configuration of a semiconductor device 15 according to a first embodiment of the invention;

FIG. 2 is a block diagram showing a configuration of a memory bank region 60 and data control circuit 61 shown in FIG. 1;

FIG. 3 is an enlarged view of memory bank BANK_0 in FIG. 2;

FIG. 4 is a timing chart illustrating a normal read operation of the semiconductor device 15;

FIG. 5 is an example of a circuit diagram of a Pass/Fail data output circuit;

FIG. 6 is an example of a circuit diagram of a test control circuit 61a;

FIG. 7 is a timing chart illustrating a test operation of the semiconductor device 15;

FIGS. 8A to 8C are diagrams showing output waveforms of test data in the first embodiment; and

FIGS. 9A and 9B are diagrams showing output waveforms of test data in a second embodiment.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

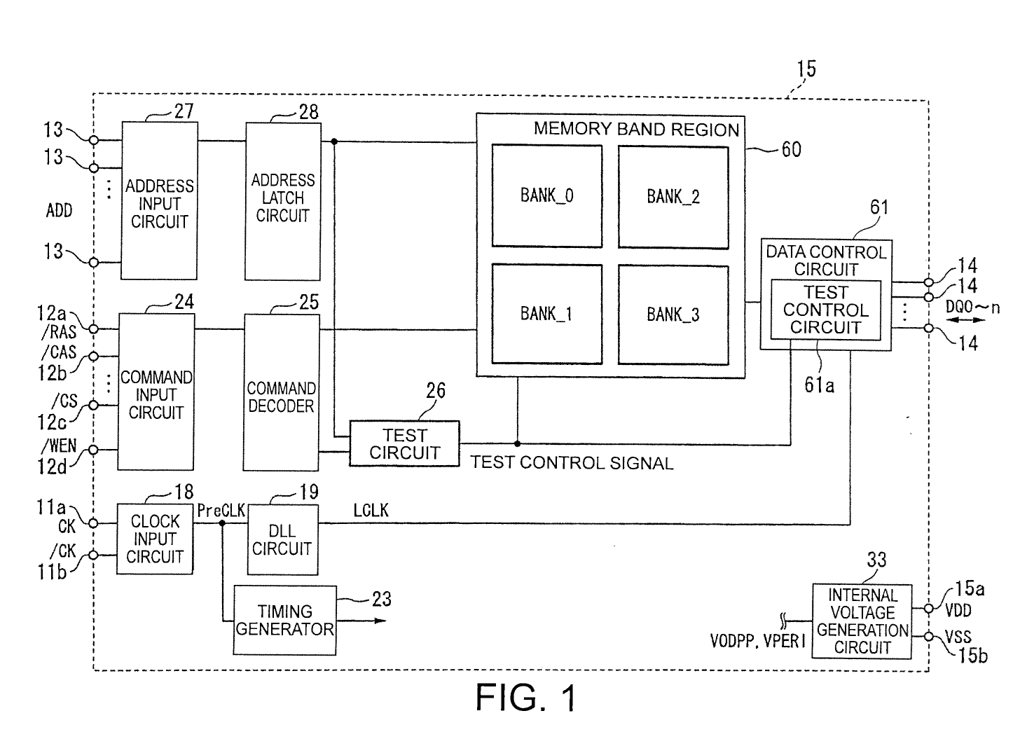

FIG. 1 is a schematic configuration diagram of an example of a semiconductor device to which the invention is applied. Specifically, a semiconductor device 15 shown here is a SDRAM (Synchronous Dynamic Random Access Memory) operating in synchronization with a clock signal supplied from the outside. All the circuit blocks shown in FIG. 1 are formed on the same semiconductor chip made of monocrystalline silicon. The circuit blocks are composed of a plurality of transistors such as PMOS transistors (P-channel MOS transistors) and NMOS transistors (N-channel MOS transistors). In FIG. 1, those denoted by small circles are pads serving as external terminals provided in the semiconductor chip.

The semiconductor device 15 includes a clock input circuit 18, a DLL circuit 19, a timing generator 23, a command input circuit 24, a command decoder 25, a test circuit 26, an address input circuit 27, and an address latch circuit 28. The semiconductor device 15 further includes an internal voltage generation circuit 33, a memory bank region 60, and a data control circuit 61.

The semiconductor device 15 includes the memory bank region 60 and the data control circuit 61. The memory bank region 60 outputs, in response to a test control signal output by the test circuit 26, a plurality of (two, in this embodiment) detection results (error data) respectively corresponding to a plurality of memory cell groups in each of memory banks BANK_0 to BANK_3.

The data control circuit 61 includes a test control circuit 61, which compresses eight pieces of error data in total output from the memory banks BANK_0 to BANK_3 into six pieces of compressed test data by means of error data synthesis circuits provided in the test control circuit 61a, and outputs them.

The six pieces of compressed test data are output as test data from data input/output terminals 14.

The voltage level of each of these six pieces of test data output by the data input/output terminals 14 is determined by an external semiconductor tester or the like whether it is H (high) level or L (low) level.

In the test operation of the semiconductor device 15, two pieces of error data are output from each of the memory banks, and thus eight pieces in total are output. The semiconductor device 15 does not output these eight pieces of error data directly as test data, but outputs them as six pieces of compressed test data. This enables the tester to shorten the time required for determination. Details of the test operation will be described later in detail. A general outline of the semiconductor device 15 will be described first below.

The semiconductor device 15 has external terminals including clock terminals 11a and 11b, command terminals 12a to 12d, address terminals 13, data input/output terminals 14, and power supply terminals 15a and 15b. Although the semiconductor device 15 additionally has a data strobe terminal, a reset terminal and so on, these terminals are omitted from the drawing.

The clock terminals 11a and 11b are supplied with external clock signals CK and /CK, respectively, and the supplied external clock signals CK and /CK are input to the clock input circuit 18. Herein, a signal denoted by letters with a slash (/) before the same represents an inversion signal of its corresponding signal, or a low active signal. Therefore, the external clock signals CK and /CK are mutually complementary signals.

A clock input circuit 18 generates a single-phase internal clock signal PreCLK based on the external clock signals CK and /CK, and supplies it to the DLL circuit 19 and the timing generator 23. The DLL circuit 19 generates a phase-controlled internal clock LCLK based on the internal clock signal PreCLK, and supplies it to the data control circuit 61.

The timing generator 23 supplies, based on the internal clock signal PreCLK, an internal clock signal that serves as an operation reference signal to other circuits in the semiconductor device 15.

The command terminals 12a to 12d are terminals supplied with a row address strobe signal /RAS, a column address strobe signal /CAS, a chip select signal /CS, and a write enable signal MIEN, respectively. A command signal CMD is formed by a combination of the signals input to these terminals.

The command signal CMD is input to the command input circuit 24. The command decoder 25 generates various types of internal command signals ICMD (internal ACT command signal, internal read command signal, internal test command signal and the like) by holding or decoding the command signal CMD received via the command input circuit 24.

The internal command signals ICMD are supplied to the memory bank region 60 and the circuits including the test circuit 26.

The address terminals 13 are terminals supplied with an address signal ADD, and the supplied address signal ADD is input to the address input circuit 27. An output of the address input circuit 27 is input to the address latch circuit 28. A bank address in the address signal ADD latched by the latch circuit 28 is input to the memory banks BANK. A row address is input in common to row decoders of the memory banks BANK. A column address is input in common to column decoders of the memory banks BANK. In order to enter the test mode, the address signal ADD is input also to the test circuit 26, so that the test circuit 26 outputs a test control signal to the memory bank region 60.

The data input/output terminals 14 are terminals for outputting read data DQ0 to DQn and inputting write data DQ0 to DQn, and connected to the data control circuit 61. During a read operation, the data control circuit 61 outputs the read data from the memory bank region 60 serially as read data DQ0 to DQn to the data input/output terminals 14 in synchronization with the internal clock LCLK. During a write operation, the data control circuit 61 outputs the write data DQ0 to DQn from the data input/output terminals 14 in parallel to the memory bank region 60 in synchronization with the internal clock LCLK. While the number of the data input/output terminals 14 is plural as shown in FIG. 1, it may be any value such as 4, 8, or 16.

The power supply terminals 15a and 15b are terminals which are supplied with an external voltage VDD and ground voltage VSS, respectively. Herein, a voltage between the external voltage VDD and the ground voltage VSS may be referred to simply as the external voltage VDD″. The power supply terminals 15a and 15b are connected to the internal voltage generation circuit 33. The external voltage VDD is supplied to the internal voltage generation circuit 33, and the internal voltage generation circuit 33 generates a first internal voltage VODPP (of 1.6 V, for example), a second internal voltage VPERI (of 1.2 V, for example) and the like, as a plurality of internal voltages appropriate for roles of the internal circuits.

The memory bank region 60 includes memory banks BANK_0 to BANK_3.

Each memory bank BANK_k (k=0 to 3) includes a plurality of memory cell array regions each of which includes a plurality of word lines, a plurality of bit lines, and a plurality of memory cells disposed at intersections of the word and bit lines. Each memory bank BANK_k (k=0 to 3) constitutes an unit capable of an independent operation such as read or write operation to or from the memory cells or refresh operation for the memory cells (operation performed based on an internal command signal supplied from the operations command decoder 25). The memory bank BANK_0, for example, is activated by input of an ACT command (active command) into the command input circuit 24 to perform operations according to the ACT command (word line selection and sense operation).

Since the command input circuit 24, the data control circuit 61 and so on are shared by the memory banks, the memory bank BANK_1 cannot receive any other command to perform an operation according to the command at the same time with the memory bank BANK_0. However, during a period from when the memory bank BANK_0 receives the ACT command to when it receives RD command (read command) corresponding to a data read operation or a WT command (write command) corresponding to a data write operation, or a during period after the memory bank BANK_0 has received the commands, the memory bank BANK_1 is activated once a REF command (refresh command) for example, is input to the command input circuit 24 and allowed to perform an operation according to the refresh command (word line selection and sense operation).

In this embodiment, each of the memory banks BANK_0 to BANK_3 is activated by input of a TEST command (test command) into the command input circuit 24. When an ACT command and a RD command are sequentially input into the command input circuit 24 after that, each of the memory banks BANK_0 to BANK_3 performs an operation according to the ACT command (word line selection and sense operation) and an operation according to the RD command (data read operation).

Although four memory banks are provided in the memory bank region 60 in FIG. 1, the number of memory banks is not limited to four, but may be any plural number such as eight.

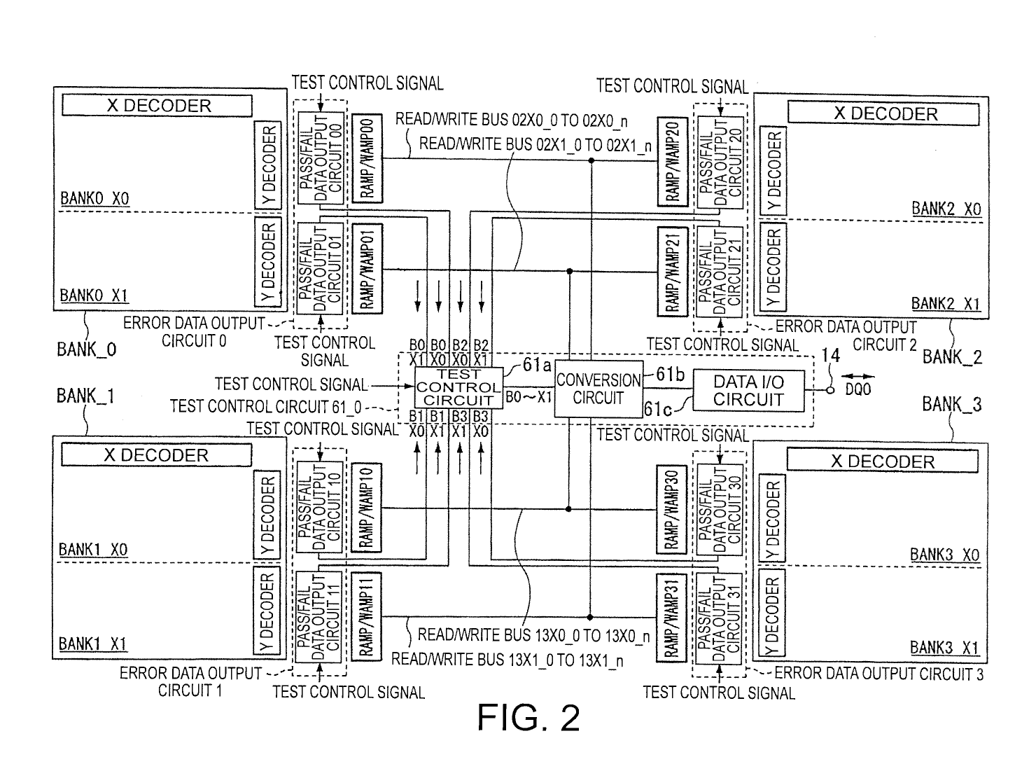

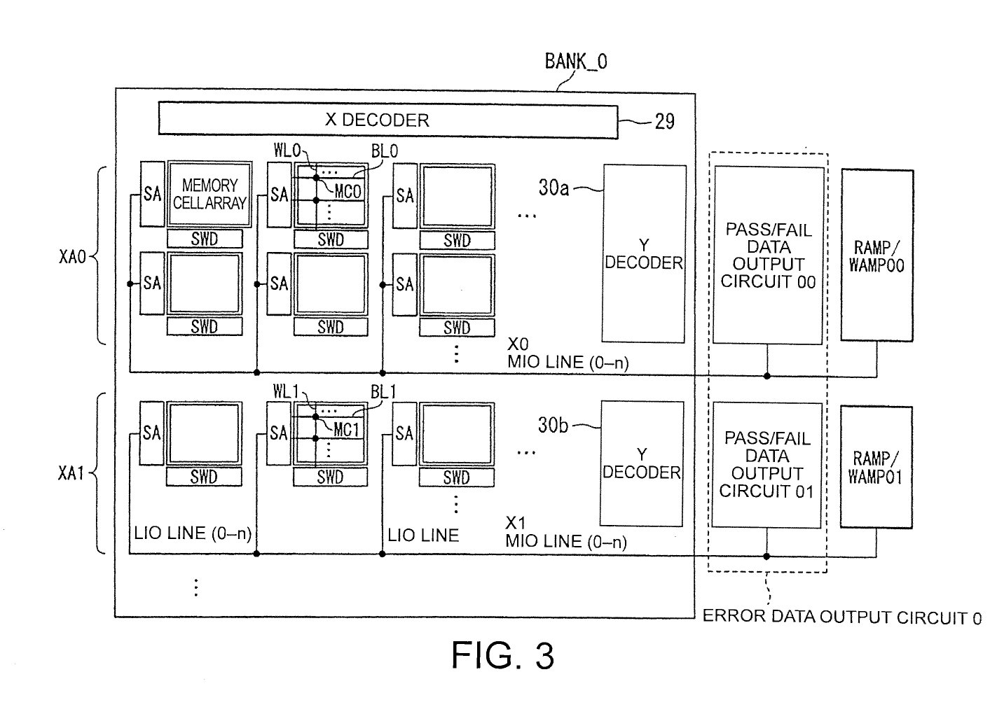

FIG. 2 is a detailed circuit block diagram showing the memory bank region 60 and the data control circuit 61. FIG. 3 is an enlarged view of the memory bank BANK_0 in the memory bank region 60.

As shown in FIG. 2, each of the banks (the memory banks BANK_0 to BANK_3) in the memory bank region 60 is divided into two regions which are selectable for example by a row address XA0 and a row address XA1. The memory bank BANK_0 is divided into a sub memory bank BANK0_X0 activated (a word line is selected) by the row address XA0 and a sub memory bank BANK0_X1 activated by the row address XA1. Likewise, the memory bank BANK_1 is divided into a sub memory bank BANK1_X0 and a sub memory bank BANK1_X1 by row addresses (X0, X1). The memory bank BANK_2 is divided into a sub memory bank BANK2_X0 and a sub memory bank BANK2_{—×}1 by row addresses (X0, X1). The memory bank BANK_3 is divided into a sub memory bank BANK3_X0 and a sub memory bank BANK3_1 by row addresses (X0, X1).

An error data output circuit and a read/write amplifier are provided adjacent to each of the sub memory banks thus divided.

A Pass/Fail data output circuit 00 constituting a part of the error data output circuit 0 is provided in correspondence with the sub memory bank BANK0_X0 and outputs error data B0X0 to the test control circuit 61a.

A read/write amplifier RAMP/WAMP00 is provided in correspondence with the sub memory bank BANK0_X0 and connected to a conversion circuit 61b via read/write buses 02X0_0 to 02X0_n.

Similarly, a Pass/Fail data output circuit 01 constituting another part of the error data output circuit 0 is provided in correspondence with the sub memory bank BANK0_X1 and outputs error data B0X1 to the test control circuit 61a. A read/write amplifier RAMP/WAMP01 is provided in correspondence with the sub memory bank BANK0_X1 and connected to the conversion circuit 61b via read/write buses 02X1_0 to 02X1_n.

A Pass/Fail data output circuit 10 constituting a part of the error data output circuit 1 is provided in correspondence with the sub memory bank BANK1_X0 and outputs error data B1X0 to the test control circuit 61a. A read/write amplifier RAMP/WAMP10 is provided in correspondence with the sub memory bank BANK1_X0 and connected to the conversion circuit 61b via read/write buses 13X0_0 to 13X0_n.

Similarly, a Pass/Fail data output circuit 11 constituting another part of the error data output circuit 1 is provided in correspondence with the sub memory bank BANK1_X1 and outputs error data B1X1 to the test control circuit 61a. A read/write amplifier RAMP/WAMP11 is provided in correspondence with the sub memory bank BANK1_X1 and connected to the conversion circuit 61b via read/write buses 13X1_0 to 13X1_n.

A Pass/Fail data output circuit 20 constituting a part of the error data output circuit 2 is provided in correspondence with the sub memory bank BANK2_X0 and outputs error data B2X0 to the test control circuit 61a. A read/write amplifier RAMP/WAMP20 is provided in correspondence with the sub memory bank BANK2_X0 and connected to the conversion circuit 61b via read/write buses 02X0_0 to 02X0_n.

Similarly, a Pass/Fail data output circuit 21 constituting another part of the error data output circuit 2 is provided in correspondence with the sub memory bank BANK2_X1 and outputs error data B2X1 to the test control circuit 61a. A read/write amplifier RAMP/WAMP21 is provided in correspondence with the sub memory bank BANK2_X1 and connected to the conversion circuit 61b via read/write buses 02X1_0 to 02X1_n.

A Pass/Fail data output circuit 30 constituting a part of the error data output circuit 3 is provided in correspondence with the sub memory bank BANK3_X0 and outputs error data B3X0 to the test control circuit 61a. A read/write amplifier RAMP/WAMP30 is provided in correspondence with the sub memory bank BANK3_X0 and connected to the conversion circuit 61b via read/write buses 13X0_0 to 13X0_n.

Similarly, a Pass/Fail data output circuit 31 constituting another part of the error data output circuit 3 is provided in correspondence with the sub memory bank BANK3_X1 and outputs error data B3X1 to the test control circuit 61a. A read/write amplifier RAMP/WAMP31 is provided in correspondence with the sub memory bank BANK3_X1 and connected to the conversion circuit 61b via read/write buses 13X1_0 to 13X1_n.

A data control circuit 61_0 includes the test control circuit 61a, the conversion circuit 61b, and a data input/output circuit 61c.

In a read operation, a selected one of the read/write amplifiers amplifies a voltage on a main I/O line (not shown in FIG. 2) and outputs the amplified result to the conversion circuit 61b via a corresponding read/write bus. In a write operation, a selected one of the read/write amplifiers amplifies the write data input from the conversion circuit 61b via the read/write bus and generates a difference voltage on the main I/O line based on the write data.

In a read operation, the conversion circuit 61b converts read data input via (n+1) read/write buses into serial data, and outputs the serial data to the data input/output circuit 61c. The data input/output circuit 61c synchronizes the serial data input from the conversion circuit 61b with the internal clock LCLK input from the DLL circuit 19, and outputs the same as read data DQ0 through the data input/output terminals 14.

In a write operation, the data input/output circuit 61c synchronizes the serial data input as write data DQ0 through the data input/output terminals 14 with the internal clock LCLK and outputs the same to the conversion circuit 61b. The conversion circuit 61b converts the serial data input from the data input/output circuit 61c into parallel data, and outputs the converted parallel data to the read/write amplifier via (n+1) read/write buses.

Meanwhile, during a test operation, all the read/write amplifiers are deactivated. The test control circuit 61a contracts (synthesizes) 8-bit error data B0X0 to error data B3X1 input from the error data output circuits 0 to 3 to generate test data B0 to B3 (4 bits). Specifically, the test control circuit 61a contracts (synthesizes) the error data from the two sub memory banks in each memory bank (error data B0X0 and error data B0X1, error data B1X0 and error data B1X1, error data B2X0 and error data B2X1, error data B3X0 and error data B3X1) to generate test data B0 to B3 (4 bits).

The test control circuit 61a contracts (synthesize) error data (error data B0X0, error data B1X0, error data B2X0, error data B3X0) from the sub memory banks indicated by the row address XA0 in each of the memory banks and generates test data X0.

The test control circuit 61a further contracts (synthesize) error data (error data B0X1, error data B1X1, error data B2X1, error data B3X1) from the sub memory banks indicated by the row address XA1 in each of the memory banks and generates test data X1.

Thus, the test control circuit 61a synthesizes 8-bit error data and outputs 6-bit test data to the conversion circuit 61b (details to be described later). The test data contains test data B0 to B3 indicating whether or not any of the memory banks is defective, test data X0 indicating whether or not there is a defect in the region indicated by the row address XA0 in each memory bank, and test data X1 indicating whether or not there is a defect in the region indicated by the row address XA1 in each memory bank.

In a test operation, the conversion circuit 61b converts the synthesized data output by the test control circuit 61a into serial data, and outputs the serial data to the data input/output circuit 61c. The data input/output circuit 61c synchronizes the serial data received from the conversion circuit 61b with the internal clock LCLK from the DLL circuit 19, and outputs the same as read data DQ0 through the data input/output terminals 14.

FIG. 2 shows selectively a part of the memory bank region 60 corresponding to one of the data input/output terminals 14 for inputting and outputting the read data DQ0 or the write data 000. As for the other data input/output terminals 14 for inputting and outputting data DQ1 to DQn as well, the data control circuit 61 may be provided for each of the data input/output terminals 14 so that read data DQ1 to DQn or write data DQ1 to DQn are input and output.

A block configuration of the memory banks BANK_0 to BANK_3 will be described with reference to FIG. 3. Since these memory banks have an identical block configuration, only the memory bank BANK_0 will be described as a representative example while description of the other memory banks will be omitted.

FIG. 3 is an enlarged view of the memory bank BANK_0 shown in FIG. 2.

As shown in FIG. 3, the memory bank BANK_0 has an X decoder 29 (row decoder), Y decoders 30a and 30b (column decoders), a plurality of memory cell arrays, a plurality of sense amplifiers SA provided in correspondence with the memory cell arrays, and a plurality of sub word drivers SWD provided in correspondence with the memory cell arrays.

In each of the memory cell arrays, a memory cell is arranged at the intersection between a word line and a bit line.

As shown in FIG. 3, for example, a memory cell MC0 is arranged at the intersection between a word line WL0 and a bit line BL0, while a memory cell MC1 is arranged at the intersection between a word line WL1 and a bit line BL1.

The X decoder 29 receives a bank address and a part of the row addresses, for example, from the address latch circuit 28 shown in FIG. 1. Based on the input addresses, the X decoder 29 drives a main word line (not shown in FIG. 3) extending in a vertical direction to the X decoder 29, that is, extending in parallel to the word line WL0 shown in FIG. 3.

The sub word driver SWD receives the remaining part of the row addresses input to the X decoder 29. When the main word line is at H (high) level, the sub word driver SWD drives one word line in the memory cell array where the sub word driver SWD is arranged, for example the word line WL0 to “H” level, based on the input row addresses. This selects all the memory cells including the memory cell MC0 on the word line WL0. However, the main word line can be configured to be activated at L (low) level.

In a normal read operation or write operation, a word line in a memory cell array is driven to “H” level and a memory cell connected to this word line is selected, in either the region indicated by the row address XA0 (sub memory bank BANK0_X0) or the region indicated by the row address XA1 (sub memory bank BANK0_X1).

In FIG. 3, the sub memory bank BANK0_X0 and the sub memory bank BANK0_X1 are divided into two regions activated by the row address XA0 and the row address XA1.

The row address XA0 and the row address XA1 are different from each other in the logic (0 or 1) of the most significant one bit of a plurality of bits forming the row address. When the most significant bit is at “H” level (logic 1), the word line in the region indicated by the row address XA0 is selected, and when the most significant bit is at “L” level (logic 0), the word line in the region indicated by the row address XA1 is selected, whereby the respective sub memory banks are activated. Although, in this embodiment, the memory bank is divided into two, it may be divided into other numbers depending on the number of address bits. For example, it may be divided into four by using 2-bit addresses, or into eight by using 3-bit addresses.

In a test operation, by reception of a test control signal from the test circuit 26, the word line in the region indicated by the row address XA0 and the word line in the region indicated by the row address XA1 are both driven to “H” level regardless of the logic of the most significant one bit of a plurality of bits forming the row address. In FIG. 3, for example, the word line WL0 and the word line WL1 are driven to “H” level, and all the memory cells including the memory cell MC0 on the word line WL0 and all the memory cells including the memory cell MC1 on the word line WL1 are selected.

The sense amplifier SA amplifies a difference voltage between a bit line connected to the selected memory cell and a bit line (not shown in the drawing) constituting a pair therewith. When the memory cell MC0 stores “H” level, for example, the bit line BL0 is driven to “H” level. When the memory cell MC1 stores “L” level, the bit line BL1 is driven to “L” level.

A Y decoder 30a and Y decoder 30b (column decoders) receive an input of a column address from the address latch circuit 28. Based on the received column address, the Y decoder 30a and the Y decoder 30b connect the bit lines in the memory cell arrays in the memory bank BANK_0 to the main I/O lines MIO_0 to MIO_n, after the bit lines are amplified by the sense amplifiers SA.

In this embodiment, n is equal to seven. In a normal read operation or write operation, one memory cell array in either the sub memory bank BANK0_X0 or the sub memory bank BANK0_X1 is selected by the column address YAn. Eight bit lines of the selected memory cell array are amplified by the sense amplifiers SA and then connected to the main I/O lines MIO_0 to MIO_7, respectively.

It is assumed here that memory cells of a memory cell array in the sub memory bank BANK0_X0 is selected by a word line. In this case, based on the column address YAn input to the Y decoder 30a, eight bit lines in the memory cell array are connected to the X0 main I/O lines MIO_0 to MIO_7 after the bit lines are amplified by the sense amplifiers SA. In this manner, data in the eight memory cells (first memory cell group) is read out onto the eight main I/O lines.

Alternatively, in a case that memory cells of a memory cell array in the sub memory bank BANK0_X1 is selected by a word line, based on the column address YAn input to the Y decoder 30b, eight bit lines in the memory cell array are connected to the X1 main I/O lines MIO_0 to MIO_7 after the bit lines are amplified by the sense amplifiers SA. In this manner, data in the eight memory cells (second memory cell group) is read out onto the eight main I/O lines.

In a test operation, the Y decoders 30a and 30b operate together to retrieve data in the eight memory cells onto the eight main I/O lines, respectively. Specifically, based on a column address YAn input to the Y decoder 30a, eight bit lines in a memory cell array in the sub memory bank BANK0_X0 are connected to the X0 main I/O lines MIO_0 to MIO_7, respectively, after the bit lines are amplified by the sense amplifiers SA. In this manner, data in the eight memory cells (first memory cell group) is read out from the sub memory bank BANK0_X0 onto the eight main I/O lines. Similarly, based on a column address YAn input to the Y decoder 30b, eight bit lines in a memory cell array in the sub memory bank BANK0_X1 are connected to the X1 main I/O lines MIO_0 to MIO_7, respectively, after the bit lines are amplified by the sense amplifiers SA. In this manner, data in the eight memory cells (second memory cell group) is read out from the sub memory bank BANK0_X1 onto the eight main I/O lines.

The read/write amplifier RAMP/WAMP00 provided in correspondence with the sub memory bank BANK0_X0 is connected to the X0 main I/O lines MIO_0 to MIO_7.

The read/write amplifier RAMP/WAMP00 amplifies the voltage on each of the X0 main I/O lines MIO_0 to MIO_7 which have been connected to the bit lines in a normal read operation. The read/write amplifier RAMP/WAMP00 outputs the amplified result (8 bits) to the conversion circuit 61b via the read/write buses 02X0_0 to 02X0_n shown in FIG. 2. Thus, data in the selected memory cell are input to the conversion circuit 61b as read data.

The read/write amplifier RAMP/WAMP00 drives each of the X0 main I/O lines MIO_0 to MIO_7 which have been connected to the bit lines in a normal write operation, according to a voltage level input from the conversion circuit 61b via the read/write buses 02X0_0 to 02X0_n. The read/write amplifier RAMP/WAMP00 thus drives the bit line connected to the main I/O line by means of the Y decoder 30a together with the sense amplifier SA connected to the bit line and writes write data in the selected memory cell.

The read/write amplifier RAMP/WAMP00 can be configured to be inactivated during a test operation not to perform amplification. In the test operation, the Pass/Fail data output circuit 00 generates error data B0X0 corresponding to eight memory cells (first memory cell group) based on the voltage level on the X0 main I/O lines MIO_0 to MIO_7, and outputs the generated error data to the test control circuit 61a shown in FIG. 2. However, the configuration may be such that the read/write amplifier RAMP/WAMP00 is activated during the test operation and after the amplification by the read/write amplifier RAMP/WAMP0 is completed, error data B0X0 is generated based on the result of this. The configuration of the Pass/Fail data output circuit 00 will be described later.

The read/write amplifier RAMP/WAMP01 provided in correspondence with the sub memory bank BANK0_X1 is connected to the X1 main I/O lines MIO_0 to MIO_7.

The read/write amplifier RAMP/WAMP01 amplifies, like the read/write amplifier RAMP/WAMP001, the voltage on each of the X1 main I/O lines MIO_0 to MIO_7 which have been connected to the bit lines in a normal read operation. The read/write amplifier RAMP/WAMP01 outputs the amplified result (8 bits) to the conversion circuit 61b via the read/write buses 02X1_0 to 02X1_n shown in FIG. 2. Thus, data in the selected memory cell are input to the conversion circuit 61b as read data.

The read/write amplifier RAMP/WAMP01 drives each of the X1 main I/O lines MIO_0 to MIO_7 which have been connected to the bit lines in a normal write operation, according to a voltage level input from the conversion circuit 61b via the read/write buses 02X1_0 to 02X1_n. The read/write amplifier RAMP/WAMP01 thus drives the bit line connected to the main I/O line by means of the Y decoder 30b together with the sense amplifier SA connected to the bit line and writes write data in the selected memory cell.

In the test operation, the Pass/Fail data output circuit 01 generates error data B0X1 corresponding to eight memory cells (second memory cell group) based on the voltage level on the X1 main I/O lines MIO_0 to MIO_7, and outputs the generated error data to the test control circuit 61a. The configuration of the Pass/Fail data output circuit 01 will be described later.

Before describing the configuration relating to test operation of the test control circuit 61a, operation of the semiconductor device 15 in a normal read operation will be described using a timing chart.

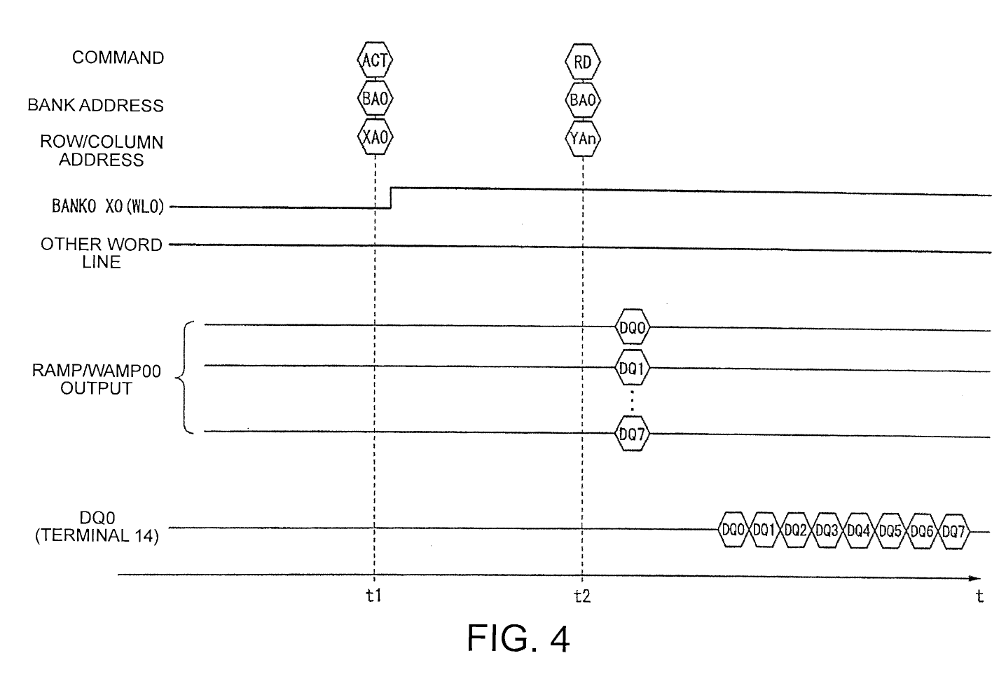

FIG. 4 is a timing chart during a normal read operation of the semiconductor device 15.

FIG. 4 illustrates a case in which data of eight bits in total stored in eight memory cells in a memory cell array in the sub memory bank BANK0_X0 shown in FIG. 2 is output to the outside of the semiconductor device 15.

At time t1, an ACT command for activating the semiconductor device 15 is input as a command signal CMD to the command input circuit 24 from a tester (semiconductor device tester) or a memory controller (hereafter, collectively referred to as the “tester”). The command input circuit 24 receives the ACT command in synchronization with external clock signals CK and /CK.

The command decoder 25 generates an internal command signal ICMD (internal ACT command signal) by holding or decoding the ACT command, and outputs the internal command signal ICMD to the circuits in the semiconductor device 15.

The address input circuit 27 acquires the bank address BA0 and the row address XA0 input at the same time with the ACT command, and outputs these addresses to the address latch circuit 28. The address latch circuit 28 latches the bank address BA0 and the row address XA0, while outputting them to the memory bank region 60.

In the memory bank BANK_0 of the memory bank region 60, receiving the bank address BA0, the X decoder 29 drives the main word line based on the bank address BA0 and the row address XA0. The sub word driver SWD also drives the word line based on the row address XA0. For example, the word line WL0 in the sub memory bank BANK0_X0 is driven, and all the memory cells connected to the word line WL0, including the memory cell MC0, are connected to the corresponding bit lines, respectively.

At time t2, the command input circuit 24 receives, as the command signal CMD, a RD command (read command) instructing the semiconductor device 15 to output data stored in the memory cells. The command input circuit 24 acquires the RD command in synchronization with the external clock signals CK and /CK.

The command decoder 25 generates an internal command signal ICMD (internal read command signal) by holding or decoding the RD command, and outputs the internal command signal ICMD to the circuits in the semiconductor device 15.

The address input circuit 27 acquires a bank address BA0 and a column address YAn input at the same time with the RD command, and outputs these addresses to the address latch circuit 28. The address latch circuit 28 latches the bank address BA0 and the column address YAn, while outputting these addresses to the memory bank region 60.

In the memory bank BANK_0 of the memory bank region 60, receiving the bank address BA0, the Y decoder 30a connects the eight bit lines that have been amplified by the sense amplifiers SA to the X0 main I/O lines MIO_0 to MIO_7 based on the column address YAn, and retrieves data in the eight memory cells (first memory cell group) onto the eight main I/O lines.

The read/write amplifier RAMP/WAMP00 amplifies the voltage on each of the X0 main I/O line MIO_0 to MIO_7, and outputs the amplified result (8-bit read data DQ0 to DQ7 shown in FIG. 4) to the conversion circuit 61b via the read/write buses 02X0_0 to 02X0_n.

The conversion circuit 61b in the data control circuit 61 converts the read data input thereto via the read/write buses 02X0_0 to 02X0_n into serial data, and outputs the serial data to the data input/output circuit 61c. The data input/output circuit 61c synchronizes the serial data received from the conversion circuit 61b with the internal clock LCLK from the DLL circuit 19, and outputs the synchronized data as read data (8-bit serial data DQ0 to DQ7 shown in FIG. 4) through the data input/output terminals 14.

The semiconductor device 15 is configured to output eight times as many bits of data during a test operation as that during a normal read operation, so that it is able to check whether the memory cells have stored the written data.

For example, a case will be described in which error data output circuits 0 to 3 and the conversion circuit 61b are used to output 64-bit error data.

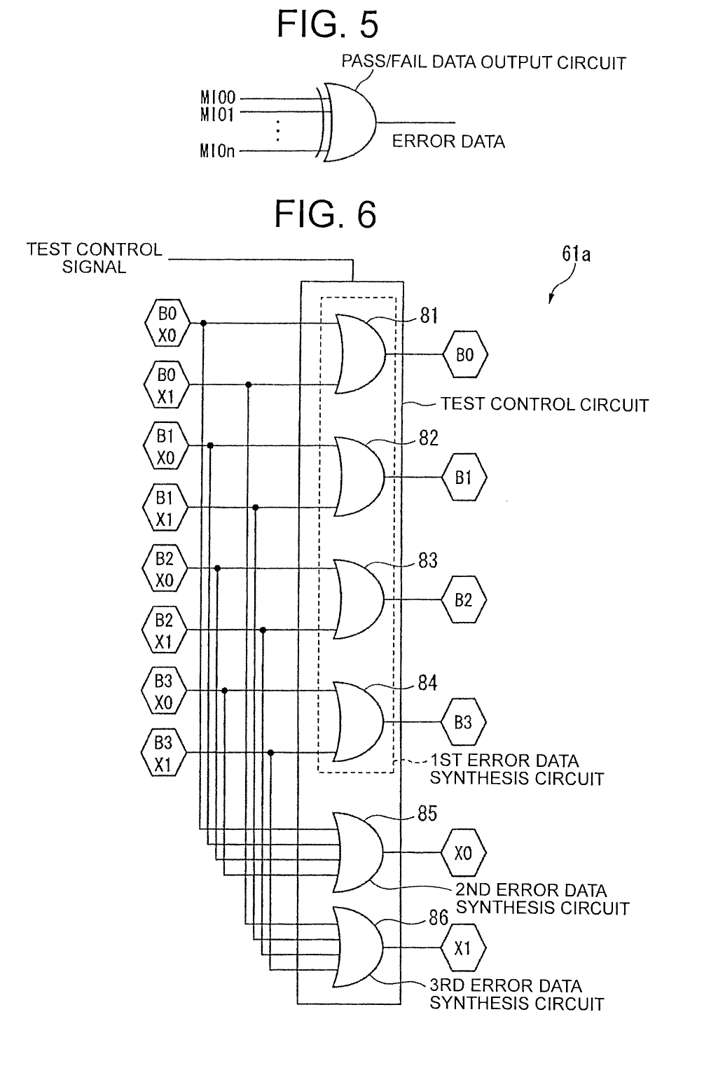

FIG. 5 shows an example of a circuit diagram representing a general configuration of Pass/Fail data output circuits 00 to 31 shown in FIG. 2.

As shown in FIG. 5, the Pass/Fail data output circuit is composed of an exclusive OR circuit (XOR circuit). The Pass/Fail data output circuit outputs error data when all the voltage levels on the main I/O lines MIO0 to MIOn match each other, specifically for example, outputs the error data of “L” level when all the voltage levels are “H” level. When not all the voltage levels of the main I/O lines MIO0 to MIOn match each other, the Pass/Fail data output circuit outputs error data of “H” level. When, for example, the voltage levels of n main I/O lines of (n+1) main I/O lines are “H” level while the voltage level of one main I/O line is “L” level, the Pass/Fail data output circuit outputs error data of “H” level. In a normal write operation preceding a test operation, identical data (“H” level or “L” level) are written and stored in memory cells (64 bits in total) the positions of which are indicated by the row addresses XA0 and XA1 and the column address YAn of the memory banks BANK_O to BANK_3.

In the test operation, data in the eight memory cells (first memory cell group) is read out from the sub memory bank BANK0_X0 of the memory bank BANK_0 onto the eight main I/O lines. The Pass/Fail data output circuit 00 corresponding to the sub memory bank BANK0_X0 outputs L-level error data B0X0 (error data corresponding to the first memory cell group) when all the voltage levels on the X0 main I/O lines MIO_0 to MIO_7 match each other, whereas outputs H-level error data B0X° when they do not match.

Similarly, data in the eight memory cells (first memory cell group) is read out from each of the sub memory bank BANK1_X0 of the memory bank BANK_1, the sub memory bank BANK2_X0 of the memory bank BANK_2 and the sub memory bank BANKS X0 of the memory bank BANK_3 onto the eight corresponding main I/O lines.

The Pass/Fail data output circuit corresponding to each of the sub memory banks BANK1_X0, BANK2_X0 and BANKS X0 outputs L-level error data (error data corresponding to the first memory cell group) when all the voltage levels on the main I/O lines match each other, whereas outputs H-level error data when they do not match.

Further, data in the eight memory cells (second memory cell group) is read out from each of the sub memory bank BANK0_X1 of the memory bank BANK_0, the sub memory bank BANK1_X1 of the memory bank BANK_1, the sub memory bank BANK2_X1 of the memory bank BANK_2 and the sub memory bank BANK3_X1 of the memory bank BANK_3 onto the eight corresponding main I/O lines.

The Pass/Fail data output circuit corresponding to each of the sub memory banks BANK1_X1, BANK1_X1, BANK2_X1 and BANK3_X1 outputs L-level error data (error data corresponding to the second memory cell group) when all the voltage levels on the main I/O lines match each other, whereas outputs H-level error data when they do not match.

The conversion circuit 61b converts the error data received from the eight Pass/Fail data output circuits 00 to 31 (B0X0 to B3X1) into serial data in this sequence, and then outputs the converted serial data to the data input/output circuit 61c. The data input/output circuit 61c synchronizes the serial data received from the conversion circuit 61b with an internal clock LCLK received from the DLL circuit 19, and outputs the synchronized data as read data DQ0 through the data input/output terminals 14.

If the error data to be output from the Pass/Fail data output circuits are output directly as test data, the data will be output in an amount corresponding to the number of selected word lines (eight in this embodiment). Therefore, the time required for the test operation may possibly be prolonged depending on the number of selected word line. In the invention, in order to avoid this problem, error data output from a plurality of Pass/Fail data output circuits are synchronized by the test control circuit 61a so that the synthesized error data is output outside the semiconductor device 15 by the conversion circuit 61b and the data input/output circuit 61c.

FIG. 6 shows an example of a circuit diagram of the test control circuit 61a.

As shown in FIG. 6, upon receiving a test control signal from the test circuit 26 in a test operation, the test control circuit 61a converts error data of eight bits in total (B0X0 to B3X1) received from the eight Pass/Fail data output circuits 00 to 31 into test data B0 to B3 and test data X0 to X1 of six bits, and outputs the converted data in parallel to the conversion circuit 61b.

As shown in FIG. 6, an example of the test control circuit 61a includes six OR circuits 81 to 86.

The OR circuit 81 calculates a logical sum of the error data B0X0 output by the Pass/Fail data output circuit 00 and the error data B0X1 output by the Pass/Fail data output circuit 01, and outputs the result as the test data B0.

The OR circuit 82 calculates a logical sum of the error data B1X0 output by the Pass/Fail data output circuit 10 and the error data B1X1 output by the Pass/Fail data output circuit 11, and outputs the result as the test data B1.

The OR circuit 83 calculates a logical sum of the error data B2X0 output by the Pass/Fail data output circuit 20 and the error data B2X1 output by the Pass/Fail data output circuit 21, and outputs the result as the test data B2.

The OR circuit 84 calculates a logical sum of the error data B3X0 output by the Pass/Fail data output circuit 30 and the error data B3X1 output by the Pass/Fail data output circuit 31, and outputs the result as the test data B3.

According to the configuration described above, each of the OR circuits 81 to 84 (first error data synthesis circuits) outputs L-level test data when both of the two types of received error (data consisting of first error data corresponding to the first memory cell group and second error data corresponding to the second memory cell group) are at “L” level, whereas when at least either one is at “H” level, the OR circuits 81 to 84 output H-level test data.

Specifically, in a test operation, when data read out from the eight memory cells (first memory cell group) in one of the two sub memory banks in each of the memory banks BANK_0 to BANK_3 match each other, and data read out from the eight memory cells (second memory cell group) in the other sub memory bank also match each other, the error data B0X0 to B3X1 output from the respective error data output circuits become “L” level, and hence the test data B0 to B3 become “L” level. In contrast, when data read out from the eight memory cells in at least one of the two sub memory banks in each of the memory banks BANK_0 to BANK_3 do not match each other, “H” level data are included in the error data B0X0 to B3X1 output from the error data output circuits. Therefore, H-level test data are included in the test data B0 to B3 output from the OR circuit 81 to 84 to which H-level error data have been input.

The OR circuit 85 calculates a logical sum of the error data B0X0 output by the Pass/Fail data output circuit 00, the error data B1X0 output by the Pass/Fail data output circuit 10, the error data B2X0 output by the Pass/Fail data output circuit 20, and the error data B3X0 output by the Pass/Fail data output circuit 30 (these error data constitute the first error data), and outputs the result as test data X0. Specifically, when data read out from the eight memory cells in the sub memory banks X0 of each of the memory banks BANK_0 to BANK_3 match each other, the test data X0 becomes “L” level, and otherwise becomes “H” level.

The OR circuit 86 calculates a logical sum of the error data B0X1 output by the Pass/Fail data output circuit 01, the error data B1X1 output by the Pass/Fail data output circuit 11, the error data B2X1 output by the Pass/Fail data output circuit 21, and the error data B3X1 output by the Pass/Fail data output circuit 31 (these error data constitute the second error data), and outputs the result as test data X1. Specifically, when data read out from the eight memory cells in the sub memory banks X1 of each of the memory banks BANK_0 to BANK_3 match each other, the test data X1 becomes “L” level, and otherwise becomes “H” level.

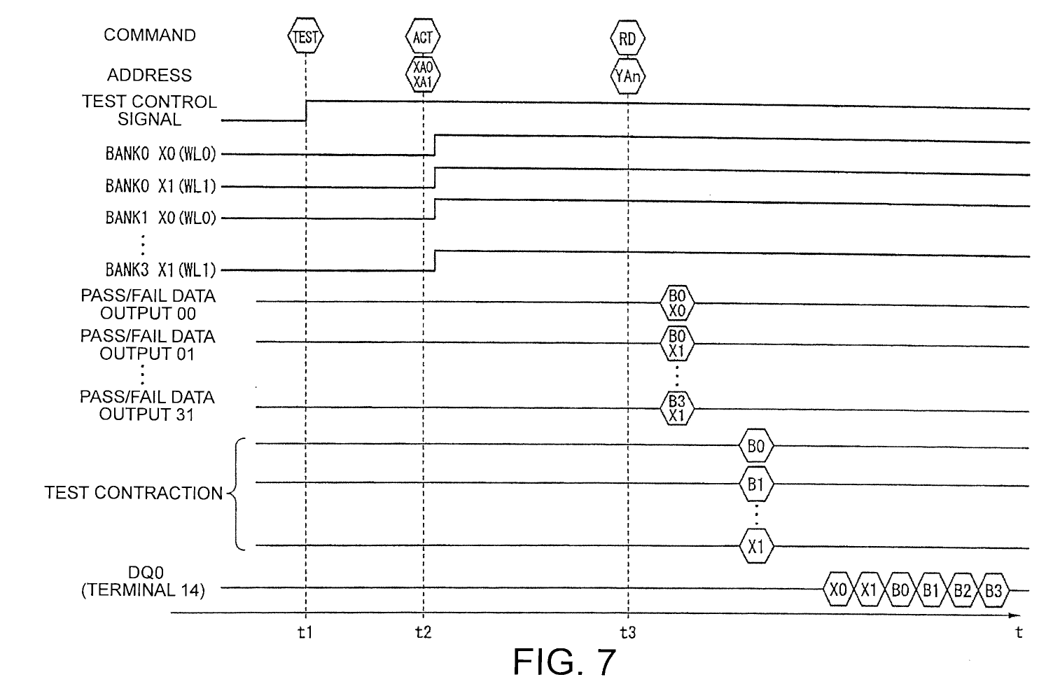

Subsequently, operation of the semiconductor device 15 during a test operation will be described with reference to a timing chart. FIG. 7 is a timing chart of the semiconductor device 15 during a test operation.

The same data (e.g. data of “H” level) are preliminarily written in all the memory cells in the memory banks BANK_0 to BANK_3.

When a test command TEST is input from the tester to command input circuit 24 of the semiconductor device 15 at time t1, the command decoder 25 generates an internal command signal ICMD (internal test command signal or the like) and outputs the generated signal to the test circuit 26. An address signal ADD input to the address input circuit 27 is also input to the test circuit 26 via the address latch circuit 28. Thus, the test circuit 26 activates the test control signal and outputs the activated signal to the memory bank region 60 and the data control circuit 61.

The test control circuit 61a shown in FIG. 6 is thus activated. The conversion circuit 61b shifts to the test mode to parallel-serial convert not only the output of the read/write amplifier but also the output of the test control circuit 61a.

At time t2, an ACT command is input to the command input circuit 24 from the tester, while at the same time, row addresses XA0, XA1 and bank addresses BA0 to BA3 (not shown) are input to the address input circuit 27. A plurality of word lines (BANK0 WL0 to BANK3 WL1) corresponding to the row addresses of the memory banks are activated. In this embodiment, two word lines WL0, WL1 are activated in each memory bank, and thus eight word lines in total are activated. The semiconductor device 15 which has shifted to the test mode may activate all the memory banks without receiving any bank address from the outside. Alternatively, the two word lines may be activated by receiving either one of the row address XA0 and XA1.

Once the word lines are activated, data are retrieved from a plurality of memory cells MC connected to the activated word lines onto a plurality of bit lines BL, respectively, and the data are amplified by the sense amplifiers SA. At time t3, a RD command is input to the command input circuit 24 from the tester, while at the same time, a column address YAn is input to the address input circuit 27. As a result, bit lines BL0 to BLn (n=7) corresponding to the column address YAn are selected.

Data retrieved onto the selected bit lines BL0 to BL7 are respectively input to the Pass/Fail data output circuits via corresponding main I/O lines. No local IO line is provided in the example shown in FIG. 3. However, a local IO line may be provided if the length of the sense amplifier SA that is the length in a word line direction is so long as to affect the access time. In this case, the local IO line is provided in a longitudinal direction of the sense amplifier in parallel with the word line, so that the sense amplifier and the main I/O line are connected via the local IO line and a preamplifier.

The Pass/Fail data output circuit respectively output error data B0X0 to B3X1 to check whether or not the data input through the main I/O lines MIO0 to MIO7 match each other. When all the data input through the main I/O lines MIO0 to MIO7 match each other, that is, all the data are at “H” level, the Pass/Fail data output circuits output L-level error data. If even one of the selected memory cells is defective, the defective memory cell will output “L” level data. Therefore, the Pass/Fail data output circuits output H-level error data.

In the test control circuit 61a, each of the first error data synthesis circuits (OR circuits 81 to 84) receives a plurality of error data B0X0 to B3X1 from error data output circuits (Pass/Fail data output circuits 00 to 31) each provided for each bank, and synthesizes the test data B0 to B3.

The second error data synthesis circuit (OR circuit 85) receives error data (error data B0X0, error data B1X0, error data B2X0, and error data B3X0) corresponding to the regions (sub memory banks) indicated by the row address XA0 of the memory banks, and synthesizes the test data X0.

The third error data synthesis circuit (OR circuit 86) receives error data (error data B0X1, error data B1X1, error data B2X1, and error data B3X1) corresponding to the regions (sub memory banks) indicated by the row address XA1 of the memory banks, and synthesizes the test data X1.

These test data X0, test data X1, and test data B0 to B3 synthesized by the test control circuit 61a are parallel-serial converted by the conversion circuit 61b as shown in FIG. 7 and output as 6-bit serial data DQ0 to the data input/output terminals 14 from the data input/output circuit 61c.

Although this embodiment has been described only in terms of the operation relating to output of the serial data DQ0, another data control circuit 61 is provided for each of other data input/output terminals 14 as well, and hence other serial data DQ1 to DQn are also output from the data input/output terminals 14.

As described above, the semiconductor device 15 has a plurality of memory banks (memory banks BANK_O to BANK_3) each having a plurality of memory cells, and a plurality of error data output circuits provided in correspondence with the plurality of memory banks, respectively. Each of the error data output circuits (Pass/Fail data output circuits 00 to 31) outputs first and second error data according to data retrieved from the selected first and second memory cell groups (memory cells in the sub memory bank designated by the row address XA0 and the sub memory bank designated by the row address XA1) of the corresponding memory banks.

The semiconductor device 15 further has a test control circuit (test control circuit 61a) having a plurality of first error data synthesis circuits (OR circuits 81 to 84) each of which synthesizes first and second error data from its corresponding error data output circuit and outputs the synthesized data, a second error data synthesis circuit (OR circuit 85) for synthesizing the first error data from the plurality of error data output circuits and outputting the synthesized error data, and a third error data synthesis circuit (OR circuit 86) for synthesizing the second error data from the plurality of error data output circuits and outputting the synthesized data.

According to the embodiment, as described above, the test control circuit 61a synthesizes error data (error data B0X0 to B3X1) corresponding to the selected memory cell groups and outputs the synthesized error data, which makes it possible to reduce the number of types of test data (test data B0 to test data B3, test data X0, and test data X1), leading to reduction of test time.

It is assumed that the semiconductor device 15 is provided, for example, with a redundancy circuit for replacing a defective memory cell in units of word lines. The semiconductor device 15 is also provided with a memory circuit (e.g. fuse circuit) for storing an address indicating the position of any defective word line. The memory circuit is mutually associated with a redundancy word line of the redundancy circuit. A defective address is stored in the memory circuit so that when this defective address is accessed from the outside, the redundancy word line associated therewith is activated in place of the defective word line. This makes it possible to select a normal memory cell in place of the defective one.

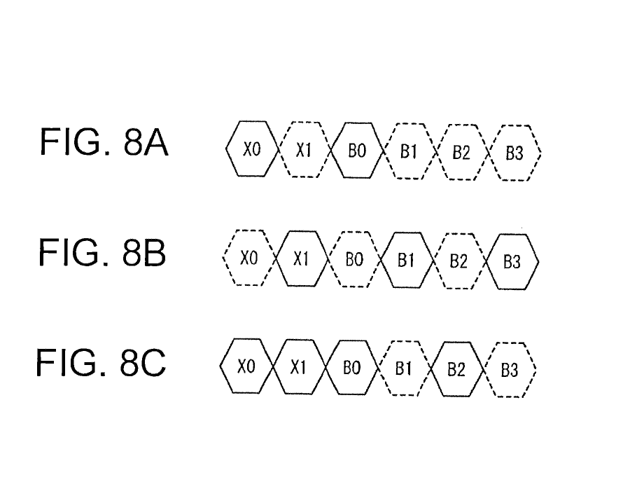

FIGS. 8A to 8C illustrate examples of waveforms of serial data output from the data input/output terminals 14 during a test operation. In FIGS. 8A to 8C, a hexagon surrounding each test data (indicating whether the test data is “L” output or “H” output) is indicated with a broken line when the output data is “H” level, whereas when the output data is “L” level, the hexagon surrounding each test data is indicated by a solid line.

As shown in FIG. 8A, when a defect exists only in the sub memory bank BANK0_X0, test data X0 and test data B0 of the 6-bit output data (serial data) output by the data input/output circuit 61c become “H” level, while the other test data become “L” level.

In this case, the defective address (address consisting of a row address XA0 and a bank address BA0) is stored in the memory circuit by cutting off the fuse circuit with use of the test data. As a result, it is made possible to replace the defective word line (the word line the position of which is indicated by the row address XA0 in the sub memory bank BANK0_X0) with a non-defective word line.

As shown in FIG. 8B, when defects exist in the sub memory banks BANK1_X1 and BANK3_X1, test data X1, test data B1 and test date B2 of the 6-bit output data (serial data) output by the data input/output circuit 61c become “H” level, while the other test data become “L” level.

In this case, the defective addresses (address consisting of a row address XA1 and a bank address BA1, and address consisting of a row address XA1 and a bank address BA3) are stored in the memory circuit by cutting off the fuse circuits with use of the test data. As a result, it is made possible to replace the two defective word lines (the word lines the position of which are indicated by the row address XA1 in the sub memory bank BANK1_X1 and the row address XA1 in the sub memory bank BANK3_X1) with non-defective word lines.

As shown in FIG. 8C, when a defect exists in the sub memory bank BANK0_X0 and the sub memory bank BANK2_X1 (defined as Case 1), or when a defect exists in the sub memory bank BANK0_X1 and the sub memory bank BANK2_X0 (defined as Case 2), the test data X0, X1, B0 and B2 of the 6-bit output data (serial data) output by the data input/output circuit 61c become “H” level, while the other test data become “L” level.

Thus, the example shown in FIG. 8C can be either Case 1 or Case 2. Therefore, when the fuse circuit is cut off with use of these test data, it must be done such that four sets of defective addresses are stored in the memory circuit. Specifically, the four sets of defective addresses are composed of an address set of the row address XA0 and the bank address BA0, an address set of the row address XA1 and the bank address BA0, an address set of the row address XA1 and the bank address BA2, and an address set of the row address XA1 and the bank address BA2. This causes four word lines (word lines the positions of which are indicated by the row address XA0 in the sub memory bank BANK0_X0, the row address XA1 in the sub memory bank BANK0_X1, the row address XA0 in the sub memory bank BANK2_X0, and the row address XA1 in the sub memory bank BANK2_X1) with non-defective word lines.

When this is done, the four word lines to be replaced may possibly include only two defective word lines, leading to a reduction of the relief efficiency. However, it is unlikely that a plurality of bits become “H” level during one retrieval of test data B0 to B3 in the test operation. Therefore, even if such a rare case occurs, it can be said that the advantage of reduction of test time obtained by retrieving 6-bit test data is greater than that obtained by retrieving 8-bit test data.

### Second Embodiment

The first embodiment has been described in terms of a case in which test data output by the semiconductor device 15 contains information of row addresses indicating the positions in a memory bank where sub memory banks are located, and this test data is output. However, the test data may contain information of column addresses as the address information.

For example, the sub memory bank BANK0_X0 in the memory bank BANK_0 is further divided into two regions (sub memory banks) selected by a column addresses YA0 and YA1.

The column address YA0 and the column address YA1 are addresses, for example, which are mutually different in logic only at the most significant one bit of a plurality of bits forming each column address. When this most significant bit is at “H” level (logic 1), for example, the bit line and the main I/O line are connected in the region indicated by the column address YA0 (defined as the sub memory bank BANK0_X00), whereas when the most significant bit is at “L” level (logic 0), the bit line and the main I/O line are connected in the region indicated by the column address YA1 (defined as the sub memory bank BANK0_X01).

When a test control signal is input from the test circuit 26 in a test operation, the sub memory bank BANK0_X00 and the sub memory bank BANK0_X01 are connected to respective Pass/Fail data output circuits (defined as the Pass/Fail data output circuit 000 and the Pass/Fail data output circuit 001) via the respective main I/O lines, regardless of the logic of the most significant one bit of the plurality of bits forming the column address.

Similarly, the sub memory bank BANK0_X1 in the memory bank BANK_0 is divided into two regions (defined as sub memory banks BANK0_X10 and BANK0_X11) selected by a column addresses YA0 and YA1. The sub memory bank BANK0_X10 and the sub memory bank BANK0_X11 are connected to respective Pass/Fail data output circuits (defined as the Pass/Fail data output circuit 010 and the Pass/Fail data output circuit 011) via the respective main I/O lines.

In the same manner, the sub memory bank BANK_X0 in the memory bank BANK_1 is divided into two regions (defined as sub memory banks BANK1_X00 and BANK1_X01) selected by a column addresses YA0 and YA1. The sub memory bank BANK1_X00 and the sub memory bank BANK1_X01 are connected to respective Pass/Fail data output circuits (defined as the Pass/Fail data output circuit 100 and the Pass/Fail data output circuit 101) via the respective main I/O lines.

Furthermore, the sub memory bank BANK1_X1 in the memory bank BANK_1 is divided into two regions (defined as sub memory banks BANK1_X10 and BANK1_X11) selected by a column addresses YA0 and YA1. The sub memory bank BANK1_X10 and the sub memory bank BANK1_X11 are connected to respective Pass/Fail data output circuits (defined as the Pass/Fail data output circuit 110 and the Pass/Fail data output circuit 111) via the respective main I/O lines.

Similarly, the sub memory bank BANK2_X0 in the memory bank BANK_2 is divided into two regions (defined as sub memory banks BANK2_X00 and BANK2_X01) selected by a column addresses YA0 and YA1. The sub memory bank BANK2_X00 and the sub memory bank BANK2_X01 are connected to respective Pass/Fail data output circuits (defined as the Pass/Fail data output circuit 200 and the Pass/Fail data output circuit 201) via the respective main I/O lines.

Furthermore, the sub memory bank BANK2_X1 in the memory bank BANK_2 is divided into two regions (defined as sub memory banks BANK2_X10 and BANK2_X11) selected by a column addresses YA0 and YA1. The sub memory bank BANK2_X10 and the sub memory bank BANK2_X11 are connected to respective Pass/Fail data output circuits (defined as the Pass/Fail data output circuit 210 and the Pass/Fail data output circuit 211) via the respective main I/O lines.

Similarly, the sub memory bank BANK3_X0 in the memory bank BANK_3 is divided into two regions (defined as sub memory banks BANK3_X00 and BANK3_X01) selected by a column addresses YA0 and YA1. The sub memory bank BANK3_X00 and the sub memory bank BANK3_X01 are connected to respective Pass/Fail data output circuits (defined as the Pass/Fail data output circuit 300 and the Pass/Fail data output circuit 301) via the respective main I/O lines.

Furthermore, the sub memory bank BANK3_X1 in the memory bank BANK_3 is divided into two regions (defined as sub memory banks BANK3_X10 and BANK3_X11) selected by a column addresses YA0 and YA1. The sub memory bank BANK3_X10 and the sub memory bank BANK3_X11 are connected to respective Pass/Fail data output circuits (defined as the Pass/Fail data output circuit 310 and the Pass/Fail data output circuit 311) via the respective main I/O lines.

Specifically, each of the memory banks shown in FIG. 2 is divided into four sub memory banks, and a Pass/Fail data output circuit is provided for each of the divided sub memory banks.

According to the configuration described above, during a test operation, data in selected memory cell groups (first and second memory cell groups) are input from the sub memory banks BANK0_00 and BANK0_01 of the memory bank BANK_0 into the Pass/Fail data output circuit 000 and Pass/Fail data output circuit 001, respectively, after being bit-line amplified by the sense amplifier SA.

The Pass/Fail data output circuit 000 outputs first error data (denoted as the error data B0X0Y0). The Pass/Fail data output circuit 001 outputs second error data (denoted as the error data B0X0Y1).

Furthermore, data in selected memory cell groups (third and fourth memory cell groups) are input from the sub memory banks BANK0_10 and BANK0_11 of the memory bank BANK_0 into the Pass/Fail data output circuit 010 and Pass/Fail data output circuit 011, respectively, after being bit-line amplified by the sense amplifier SA.

The Pass/Fail data output circuit 010 outputs third error data (denoted as the error data B0X1Y0). The Pass/Fail data output circuit 011 outputs fourth error data (denoted as the error data B0X1Y1).

Similarly, during a test operation, data in selected memory cell groups (first and second memory cell groups) are input from the sub memory banks BANK1_00 and BANK1_01 of the memory bank BANK_1 into the Pass/Fail data output circuit 100 and Pass/Fail data output circuit 101, respectively, after being bit-line amplified by the sense amplifier SA.

The Pass/Fail data output circuit 100 outputs first error data (denoted as the error data B1X0Y0). The Pass/Fail data output circuit 101 outputs second error data (denoted as the error data B1X0Y1).

Furthermore, data in selected memory cell groups (third and fourth memory cell groups) are input from the sub memory banks BANK1_10 and BANK1_11 of the memory bank BANK_1 into the Pass/Fail data output circuit 110 and Pass/Fail data output circuit 111, respectively, after being bit-line amplified by the sense amplifier SA.

The Pass/Fail data output circuit 110 outputs third error data (denoted as the error data B1X1Y0). The Pass/Fail data output circuit 111 outputs fourth error data (denoted as the error data B1X1Y1).

Similarly, during a test operation, data in selected memory cell groups (first and second memory cell groups) are input from the sub memory banks BANK2_00 and BANK2_01 of the memory bank BANK_2 into the Pass/Fail data output circuit 200 and Pass/Fail data output circuit 201, respectively, after being bit-line amplified by the sense amplifier SA.

The Pass/Fail data output circuit 200 outputs first error data (denoted as the error data B2X0Y0). The Pass/Fail data output circuit 201 outputs second error data (denoted as the error data B2X0Y1).

Furthermore, data in selected memory cell groups (third and fourth memory cell groups) are input from the sub memory banks BANK2_10 and BANK2_11 of the memory bank BANK_2 into the Pass/Fail data output circuit 210 and Pass/Fail data output circuit 211, respectively, after being bit-line amplified by the sense amplifier SA.

The Pass/Fail data output circuit 210 outputs third error data (denoted as the error data B2X1Y0). The Pass/Fail data output circuit 211 outputs fourth error data (denoted as the error data B2X1 Y1).

Similarly, during a test operation, data in selected memory cell groups (first and second memory cell groups) are input from the sub memory banks BANK3_00 and BANK3_01 of the memory bank BANK_3 into the Pass/Fail data output circuit 300 and Pass/Fail data output circuit 301, respectively, after being bit-line amplified by the sense amplifier SA.

The Pass/Fail data output circuit 300 outputs first error data (denoted as the error data B3X0Y0). The Pass/Fail data output circuit 301 outputs second error data (denoted as the error data B3X0Y1).

Furthermore, data in selected memory cell groups (third and fourth memory cell groups) are input from the sub memory banks BANK3_10 and BANK3_11 of the memory bank BANK_3 into the Pass/Fail data output circuit 310 and Pass/Fail data output circuit 311, respectively, after being bit-line amplified by the sense amplifier SA.

The Pass/Fail data output circuit 310 outputs third error data (denoted as the error data B3X1Y0). The Pass/Fail data output circuit 311 outputs fourth error data (denoted as the error data B3X1Y1).

When it is presumed that no test control circuit 61a as described above is provided for receiving the error data from the sub memory banks, 16-bit error data output by sixteen Pass/Fail data output circuits are parallel-serial converted by the conversion circuit 61b, whereby serial data are generated. The data input/output circuit 61c synchronizes the serial data received from the conversion circuit 61b with an internal clock LCLK received from the DLL circuit 19, and outputs the synchronized data as read data DQ0 (test data) through the data input/output terminals 14.

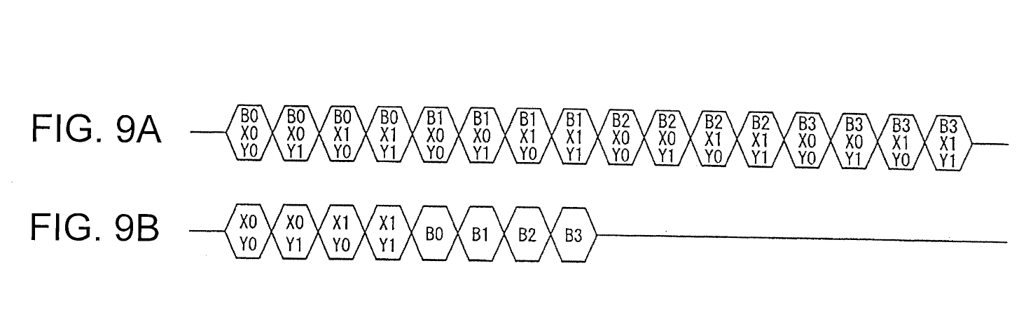

FIG. 9A illustrates a waveform of the test data. Although FIG. 9A does not show “H” level or “L” level, if there is a defective memory cell (memory cell whose data cannot be retrieved in a test operation) in a sub memory bank, test data of “H” level are output as test data corresponding to the defective memory cell, while test data of “L” level is output as test data corresponding to a non-defective memory cell.

For example, when a defective memory cell is included only in the selected memory cells (first memory cell group) in the sub memory bank BANK0_00 of the memory bank BANK_0, test data corresponding to the error data B0X0Y0 become “H” level, while test data corresponding to the other error data become “L” level.

However, according to the second embodiment in which the semiconductor device 15 is provided with a test control circuit 61a, the number of pieces of test data output during a test operation is smaller as shown in FIG. 9B in comparison with the test data shown in FIG. 9A.

The test control circuit 61a is configured in the same manner as the test control circuit shown in FIG. 6. Specifically, the test control circuit 61a has four first error data synthesis circuits respectively corresponding to four memory banks, and second to fifth error data synthesis circuits respectively corresponding to first to fourth error data.

Since the number of pieces of error data is twice as many as that in the first embodiment, each of the first error data synthesis circuits is composed of a 4-input OR circuit (denoted as the OR circuits 81a to 84a).

Like the second error data synthesis circuit and the third error data synthesis circuit (denoted as the OR circuits 85a and 85b) corresponding to the first and second memory cell groups, the third and fourth error data synthesis circuits corresponding to the third and fourth memory cell groups are also each composed of a 4-input OR circuit (denoted as the OR circuits 86a and 86b).

The OR circuit 81a calculates a logical sum of error data B0X0Y0 output by the Pass/Fail data output circuit 000, error data B0X0Y1 output by the Pass/Fail data output circuit 001, error data B0X1Y0 output by the Pass/Fail data output circuit 010, and error data B0X1Y1 output by the Pass/Fail data output circuit 011, and outputs the result as test data B0.

The OR circuit 82a calculates a logical sum of error data B1X0Y0 output by the Pass/Fail data output circuit 100, error data B1X0Y1 output by the Pass/Fail data output circuit 101, error data B1X1Y0 output by the Pass/Fail data output circuit 110, and error data B1X1Y1 output by the Pass/Fail data output circuit 111, and outputs the result as test data B1.

The OR circuit 83a calculates a logical sum of error data B2X0Y0 output by the Pass/Fail data output circuit 200, error data B2X0Y1 output by the Pass/Fail data output circuit 201, error data B2X1 Y0 output by the Pass/Fail data output circuit 210, and error data B2X1Y1 output by the Pass/Fail data output circuit 211, and outputs the result as test data B2.

The OR circuit 84a calculates a logical sum of error data B3X0Y0 output by the Pass/Fail data output circuit 300, error data B3X0Y1 output by the Pass/Fail data output circuit 301, error data B3X1Y0 output by the Pass/Fail data output circuit 310, and error data B3X1Y1 output by the Pass/Fail data output circuit 311, and outputs the result as test data B3.

The OR circuit 85a calculates a logical sum of error data B0X0Y0 output by the Pass/Fail data output circuit 000, error data B1X0Y0 output by the Pass/Fail data output circuit 100, error data B2X0Y0 output by the Pass/Fail data output circuit 200, and error data B3X0Y0 output by the Pass/Fail data output circuit 300, and outputs the result as test data X0Y0.

The OR circuit 85b calculates a logical sum of error data B0X0Y1 output by the Pass/Fail data output circuit 001, error data B1X0Y1 output by the Pass/Fail data output circuit 101, error data B2X0Y1 output by the Pass/Fail data output circuit 201, and error data B3X0Y1 output by the Pass/Fail data output circuit 301, and outputs the result as test data X0Y1.

The OR circuit 86a calculates a logical sum of error data B0X1Y0 output by the Pass/Fail data output circuit 010, error data B1X1Y0 output by the Pass/Fail data output circuit 110, error data B2X1Y0 output by the Pass/Fail data output circuit 210, and error data B3X1Y0 output by the Pass/Fail data output circuit 310, and outputs the result as test data X1Y0.

The OR circuit 86b calculates a logical sum of error data B0X1Y1 output by the Pass/Fail data output circuit 011, error data B1X1Y1 output by the Pass/Fail data output circuit 111, error data B2X1Y1 output by the Pass/Fail data output circuit 211, and error data B3X1Y1 output by the Pass/Fail data output circuit 311, and outputs the result as test data X1Y1.

Test data of eight bits output by the test control circuit 61a are parallel-serial convert by the conversion circuit 61b and serial data are generated. The data input/output circuit 61c synchronizes the serial data received from the conversion circuit 61b with an internal clock LCLK received from the DLL circuit 19, and outputs the synchronized data as read data DQ0 (test data) through the data input/output terminals 14.

FIG. 9B illustrates a waveform of the test data. Although FIG. 9B does not show “H” level or “L” level, if there is a defective memory cell (memory cell whose data cannot be retrieved in a test operation) in a sub memory bank, test data of H″ level are output as test data corresponding to the defective memory cell, while test data of “L” level are output as test data corresponding to a non-defective memory cell.

For example, when a defective memory cell is included only in the selected memory cells (first memory cell group) in the sub memory bank BANK0_00 of the memory bank BANK_0, test data B0 and X0Y0 become “H” level, while the other test data become “L” level.

When a defective memory cell is included, for example, only in the selected memory cells (second memory cell group) in the sub memory bank BANK3_11 of the memory bank BANK_3, test data B3 and X1Y1 become “H” level, while the other test data become “L” level.

Subsequently, the number of bits of the test data described in the first and second embodiments will be described.

The number of the memory banks is denoted by p (p is an integer of 2 or more). In both the first and second embodiments, p is equal to 4.

The number of bits of the row address data (row addresses used to divide the sub memory bank) indicating the positions of the first and second memory cell groups in the memory bank is denoted by q (q is an integer that is equal to or greater than 1). In both the first and second embodiments, q is equal to 1.

The number of bits of the column address data (column addresses used to divide the sub memory bank) indicating the position of the first and second memory cell groups in the memory bank is denoted by r (r is an integer that is equal to or greater than 0). In the first embodiment, r is equal to 0, whereas in the second embodiment, r is equal to 1.

The number of bits of the error data output by the Pass/Fail data output circuit (error data output circuit) is represented by p×2⁹×2^{r}. The error data is of 8 bits in the first embodiment, whereas the error data is of 16 bits in the second embodiment (see FIG. 7 and FIG. 9A, respectively).

However, the method of contraction according to the invention is not limited to this, but contraction may also be among banks. This means that by applying the invention, data output of 2″ bits can be reduced to 2×n bits at maximum regardless of combination of banks, or rows and columns.

Theoretically, the effects of the invention can be obtained by composing each of the plurality of memory banks of M (M is an integer of two or more) sub memory banks. However, in order to facilitate the selective selection of the sub memory banks with row addresses and column addresses, it is desirable that M=2^{(q+r)}.

The test data indicating that the first or second memory cell group generated by the test control circuit 61a includes a defective cell is of p bits. In both the first and second embodiments, the test data is of four bits (see FIG. 7 and FIG. 9B, respectively).

The test data indicating that the first memory cell group includes a defective cell in the plurality of memory banks, and the test data indicating that the second memory cell group includes a defective cell are both of (q+r) bits. In the first embodiment, the test data indicating that the first memory cell group includes a defective cell is the test data X0 that is of one bit, while the test data indicating that the second memory cell group includes a defective cell is the test data X1 that is of one bit (see FIG. 7). In the second embodiment, the test data indicating that the first memory cell group includes a defective cell is the test data X0Y0 and the test data X0Y1 which are of two bits, while the test data indicating that the second memory cell group includes a defective cell is the test data X1Y0 and the test data X0Y1 which are of two bits (see FIG. 9B).

The test data of (p+(q+r)×2) bits output by the test control circuit 61a are parallel-serial converted by the conversion circuit 61b, whereby serial data are generated. The data input/output circuit 61c synchronizes the serial data received from the conversion circuit 61b with the internal clock LCLK received from the DLL circuit 19, and output the synchronized data as read data DQ0 (test data) through the data input/output terminal 14.

In the first embodiment, 6-bit test data is output by the semiconductor device 15, whereas in the second embodiment, 8-bit test data is output (see FIG. 7 and FIG. 9B, respectively).

The semiconductor device 15 provided with the test control circuit 61a according to the invention is able to reduce the number of test data output serially, in comparison with the one having no test control circuit 61a, from 8 bits to 6 bits in the first embodiment, and from 16 bits to 8 bits in the second embodiment.

Accordingly, the invention is able to provide a semiconductor device in which the test time is reduced.

The technical idea of the invention is applicable to any semiconductor device having a memory function. Further, the circuit forms in the circuit blocks and circuits for generating other control signals illustrated in the drawings are not limited to those disclosed in the embodiments.

The technical idea of the semiconductor device of the invention is applicable to a variety of semiconductor devices. For example, the invention is applicable to semiconductor devices in general such as a CPU (Central Processing Unit), a MCU (Micro Control Unit), a DSP (Digital Signal Processor), an ASIC (Application Specific Integrated Circuit), an ASSP (Application Specific Standard Product), and a memory. These semiconductor devices to which the invention is applied may take product forms such as SOC (System On Chip), MCP (Multi-Chip Package) and POP (Package On Package). This invention is thus applicable to semiconductor device having any of these product forms or package forms.

The transistor should be a field effect transistor (FET), and a variety of FETs such as MIS (Metal-Insulator Semiconductor) and TFT (Thin Film Transistor) can be used in addition to the MOS (Metal Oxide Semiconductor). A bipolar transistor may be provided in a part of the device.

Further, a NMOS transistor (N-channel MOS transistor) is a typical example of a first conductivity type transistor, and a PMOS transistor (P-channel MOS transistor) is a typical example of a second conductivity type transistor.

The various disclosed elements can be combined or selected in a variety of ways within the scope of the invention defined in the appended claims. It is to be understood that the invention includes all the modifications and variations that will be apparent to those skilled in the art in light of all the disclosures and technical ideas including the claims.

What is claimed is:

1. A device comprising:
a plurality of memory banks each having a plurality of memory cells;
a plurality of error data output circuits provided in correspondence with the respective memory banks, each of the error data output circuits outputting first to M-th (M is an integer of 2 or more) error data according to first to M-th data retrieved from first to M-th memory cell groups selected from its corresponding memory bank; and
a test control circuit having a plurality of first error data synthesis circuits each of which synthesizes the first to M-th error data from the corresponding one of the error data output circuits and outputs the synthesized data as first test data, and second to (M+1)-th error data synthesis circuits each of which synthesizes m-th (m is an integer of from 1 to M) error data from the error data output circuits and outputs the synthesized data as (m+1)-th test data.

2. The device according to claim 1, wherein:
M is equal to 2;
each of the plurality of error data output circuits outputs first and second error data according to the first and second retrieved data retrieved from the first and second selected memory cell groups selected from its corresponding memory bank;
each of the plurality of first error data synthesis circuits synthesizes the first and second error data from the corresponding error data output circuit and outputs the synthesized data as the first test data; and
the second error data synthesis circuit synthesizes the first error data from the error data output circuits and outputs the synthesized data as the second test data, while the third error data synthesis circuit synthesizes the second error data from the plurality of error data output circuits and outputs the synthesized data as the third test data.

3. The device according to claim 2, wherein each of the error data output circuits comprises:
a first circuit which detects whether or not a plurality of memory cell data contained in the first retrieved data retrieved from the first memory cell group match each other; and
a second circuit which detects whether or not a plurality of memory cell data contained in the second retrieved data retrieved from the second memory cell group match each other.

4. The device according to claim 2, further comprising:
a data output terminal; and
a conversion circuit which receives the plurality of first test data from the plurality of first error data synthesis circuits, the second test data and the third test data input thereto in parallel, and outputs the plurality of first test data, the second test data and the third test data in series to the data output terminal.

5. The device according to claim 4, wherein:
the plurality of error data output circuits and the test control circuit operate during a test mode;
during a normal operation mode, the first memory cell group in the first memory bank of the plurality of memory banks is selected based on an address signal input from the outside, and the plurality of memory cell data retrieved from the selected first memory cell group are input in parallel to the conversion circuit without involving the plurality of error data output circuits and the test control circuit and are output in series to the data output terminal.

6. The device according to claim 2, wherein the plurality of error data output circuits and the test control circuit operate during a test mode;
each of the plurality of memory banks further comprises a first word line connected in common to the first memory cell group, and a second word line connected in common to the second memory cell group; and
during the test mode, the first and second word lines of each of the plurality of memory banks are activated substantially simultaneously.

7. The device according to claim 1, wherein M is equal to four.

8. A device comprising:
a plurality of memory banks each having first to M-th (M is an integer of 2 or more) sub memory banks;
a plurality of error data output circuits provided in correspondence with the respective memory banks, and including first to M-th error detection circuits respectively corresponding to the first to M-th sub memory banks in the corresponding memory banks;
a plurality of first synthesis circuits respectively provided in correspondence with the plurality of error data output circuits to synthesize error data from the first to M-th error detection circuits of the corresponding error data output circuit; and
second to (M+1)-th synthesis circuits each of which synthesizes error data respectively from all the m-th (m is an integer of 1 to M) error detection circuits included in the plurality of error data output circuits.

9. The device according to claim 8, wherein each of the first to M-th error data output circuits is an exclusive OR circuit which outputs, as the error data, an exclusive logical sum of data of predetermined bits retrieved from the corresponding first to M-th sub memory banks.

10. The device according to claim 8, wherein each of the first synthesis circuits and the second to (M+1)-th synthesis circuits is an OR circuit outputting a logical sum of input signals.

11. The device according to claim 8, further comprising a parallel-serial conversion circuit which receives outputs from the plurality of first synthesis circuits and the second to (m+1)-th synthesis circuits in parallel, converting them into a serial signal, and outputs the serial signal.

12. The device according to 11, further comprising a plurality of read/write amplifiers respectively provided in correspondence with the first to M-th sub memory banks of the plurality of memory banks, wherein:
in a normal operation mode, data retrieved from the sub memory banks are supplied to the parallel-serial conversion circuit via the corresponding read/write amplifiers; and
in a test mode, data retrieved from the sub memory banks are supplied to the corresponding error detection circuits, and the error data are supplied from the error detection circuits to the parallel-serial conversion circuit.

13. The device according to claim 8, wherein:
each of the memory banks includes a plurality of memory cells which are selectable by means of a row address and a column address; and
the plurality of memory cells are arranged to form 2^{q} (q is a natural number) sub memory banks using column addresses, 2^{r} (r is an integer of 0 or more) sub memory banks using row addresses, and 2^{(q+r)} (=M) sub memory banks in total.

14. A method of operating a device including a first memory area designated by a first memory area selection information and a second memory area designated by a second memory area selection information, each of the first and second memory areas including a first memory block designated by a first memory block selection information and a second memory block designated by a second memory block selection information, the method comprising:
reading a first information stored in a memory cell in the first memory block of the first memory area, designated by the first memory area selection information and the first memory block selection information;
reading a second information stored in a memory cell in the second memory block of the first memory area, designated by the first memory area selection information and the second memory block selection information;
reading a third information stored in a memory cell in the first memory block of the second memory area, designated by the second memory area selection information and the first memory block selection information;
reading a fourth information stored in a memory cell in the second memory block of the second memory area, designated by the second memory area selection information and the second memory block selection information;
synthesizing the first and second information to produce a first data;
synthesizing the third and forth information to produce a second data;
synthesizing the first and third information to produce a third data; and
synthesizing the second and forth information to produce a fourth data.

15. The method as claimed in claim 14, further comprising:
writing same data into the memory cells in first and second memory blocks of each of the first and second memory area before the reading.

16. The method as claimed in claim 15, wherein the writing is performed during a test mode.
